(19) United States
(12) Patent Application Publication
(10) Pub. No.: US 2012/0257284 A1
(43) Pub. Date: Oct. 11, 2012

(54) IMAGING DEVICE AND DISPLAY DEVICE

(76) Inventor: Shinsuke Okamoto, Tokyo (JP)

(21) Appl. No.: 13/420,666

(22) Filed: Mar. 15, 2012

(30) Foreign Application Priority Data
Apr. 8, 2011 (JP) 2011-086801

(51) Int. Cl. G02B 27/01; H01L 27/146

(52) U.S. Cl. 359/630; 250/208.1

(57) ABSTRACT

The present disclosure provides an imaging device including: a first element for converting image light into an electric signal or generating an image on the basis of an electric signal; and a second element for converting image light into an electric signal or generating an image on the basis of an electric signal, wherein an angle of rotation of the first element about an axis in a longitudinal direction is adjustable with respect to the second element.

### BACKGROUND

The present disclosure relates to an imaging device and a display device for a user to observe a subject with both eyes, such as binoculars, a head-mounted display, or the like.

For a user to observe a subject with both eyes, binoculars have optical systems corresponding to the left eye and the right eye, respectively. In related art, inclination movement of one eyepiece unit of a left eyepiece unit and a right eyepiece unit with respect to the other eyepiece unit is proposed as a method for adjusting the optical axes of a left optical system and a right optical system (see Japanese Patent Laid-Open No. 2003-57563, for example).

### SUMMARY

In electronic binoculars using EVFs (Electronic View Finders), light entering from objective lenses is converted into image data by imaging elements such as CMOS imagers or the like, and the image data is displayed on display elements such as liquid crystal display panels or the like. A user observes the images displayed on the display elements in a state of being magnified by eyepieces. Such electronic binoculars for example need to adjust the angles of roll (angles of rotation about a longitudinal axis) of the display elements with respect to the optical axes of the eyepieces.

However, the method in the past which method is described in Patent Document 1 can adjust only an angle of pitch (angle of rotation about a lateral axis) and an angle of yaw (angle of rotation about a vertical axis), and is not sufficient for imaging devices such as electronic binoculars including EVFs or display devices which imaging devices or display devices need adjustment of an angle of roll.

It is desirable to provide an imaging device and a display device that enable the angle of roll of an imaging element or a display element to be adjusted.

According to an embodiment of the present disclosure, there is provided an imaging device including: a first element for converting image light into an electric signal or generating an image on the basis of an electric signal; and a second element for converting image light into an electric signal or generating an image on the basis of an electric signal, wherein an angle of rotation of the first element about an axis in a longitudinal direction is adjustable with respect to the second element.

In the imaging device according to the above-described embodiment of the present disclosure, the first element and the second element each convert image light into an electric signal, or generate an image on the basis of an electric signal. In this case, the angle of rotation of the first element about the axis in the longitudinal direction is adjusted with respect to the second element. Thus, the parallelisms of the image light incident on the first element and the second element or the images displayed on the first element and the second element coincide with each other, and the superimposition of the image light or the images is performed properly.

According to an embodiment of the present disclosure, there is provided a display device including: a first element for generating an image on the basis of an electric signal; and a second element for generating an image on the basis of an electric signal, wherein an angle of rotation of the first element about an axis in a longitudinal direction is adjustable with respect to the second element.

In the display device according to the above-described embodiment of the present disclosure, the first element and the second element each generate an image on the basis of an electric signal. In this case, the angle of rotation of the first element about the axis in the longitudinal direction is adjusted with respect to the second element. Thus, the parallelisms of the images displayed on the first element and the second element coincide with each other, and the images are superimposed on each other properly.

In the imaging device according to the above-described embodiment of the present disclosure or the display device according to the above-described embodiment of the present disclosure, the angle of rotation of the first element about the axis in the longitudinal direction is adjustable with respect to the second element. Thus, the angles of roll of the first element and the second element can be adjusted.

### BRIEF DESCRIPTION OF THE DRAWINGS

FIG. 1 is a diagram showing a configuration of an imaging device according to a first embodiment of the present disclosure;

FIG. 2 is a diagram showing an internal configuration of eyepiece barrels shown in FIG. 1;

FIGS. 3A, 3B, 3C, and 3D are diagrams of assistance in explaining an example of specific positions shown in FIG. 2;

FIG. 4 is a perspective view of a constitution of a base shown in FIG. 2;

FIG. 5 is a schematic sectional view taken along a line V-V in FIG. 4;

FIG. 6 is a perspective view of a constitution of a base shown in FIG. 2;

FIG. 7 is an exploded perspective view of the base shown in FIG. 6;

FIG. 8 is a schematic sectional view taken along a line VIII-VIII in FIG. 6;

FIG. 9 is an exploded perspective view of a second rotating member shown in FIG. 7;

FIG. 10 is a schematic sectional view taken along a line X-X in FIG. 6;

FIG. 11 is a diagram showing a method for adjusting the angles of rotation of EVFs shown in FIG. 1;

FIGS. 12A, 12B, 12C, and 12D are diagrams of assistance in explaining a procedure for adjusting the angles of rotation of the EVFs shown in FIG. 11;

FIG. 13 is a front view of an external appearance of the imaging device shown in FIG. 1;

FIG. 14 is a rear view of the external appearance of the imaging device;

FIG. 15 is a right side view of the external appearance of the imaging device;

FIG. 16 is a left side view of the external appearance of the imaging device;

FIG. 17 is a top view of the external appearance of the imaging device;

FIG. 18 is a bottom view of the external appearance of the imaging device;

FIG. 19 is a perspective view of the external appearance of the imaging device as viewed from the direction of a lower right;

FIG. 20 is a perspective view of the external appearance of the imaging device as viewed from the direction of an upper left;

FIG. 21 is a perspective view of an external appearance of a display device according to a second embodiment of the present disclosure;

FIG. 22 is a diagram showing a configuration of the display device shown in FIG. 21;

FIG. 23 is a diagram showing a configuration of an imaging device according to a third embodiment of the present disclosure; and

FIG. 24 is a diagram showing a method for adjusting the angles of rotation of imaging elements shown in FIG. 23.

### DETAILED DESCRIPTION OF THE PREFERRED EMBODIMENTS

Preferred embodiments of the present disclosure will hereinafter be described in detail with reference to the drawings. Incidentally, description will be made in the following order.

1. First Embodiment (Electronic Binoculars: Example of Adjusting Angles of Rotation of EVFs)

2. Second Embodiment (Head-Mounted Display: Example of Adjusting Angles of Rotation of Display Elements)

3. Third Embodiment (Electronic Binoculars: Example of Adjusting Angles of Rotation of Imaging Elements)

### First Embodiment

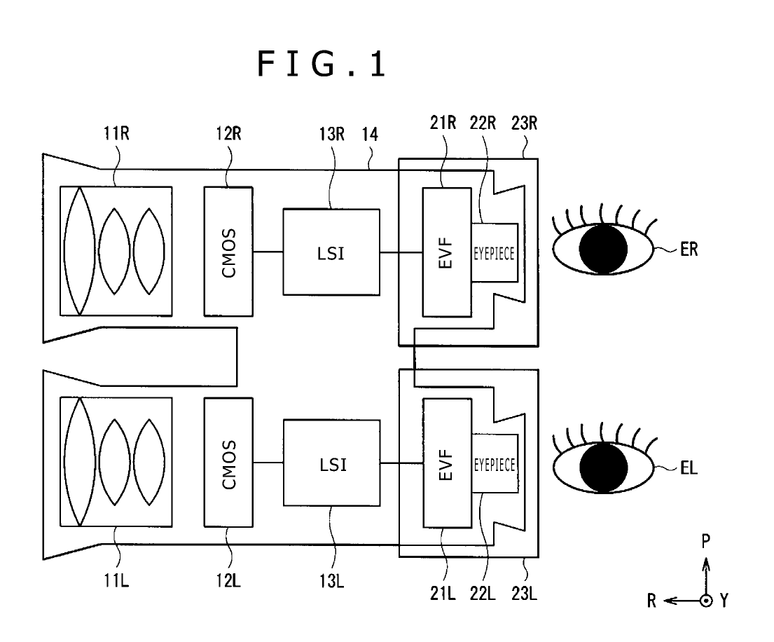

FIG. 1 schematically shows a configuration of electronic binoculars as an imaging device according to a first embodiment of the present disclosure. Incidentally, in the drawings, a direction (lateral direction) parallel with a direction of width is denoted by P, a direction (vertical direction) parallel with a direction of height is denoted by Y, and a longitudinal direction is denoted by R.

The electronic binoculars are used when a user magnifies and looks at a distant view or the like with both eyes, for example. The electronic binoculars for example include objective lenses 11L and 11R, imaging elements 12L and 12R, LSIs (Large Scale Integrated Circuits) 13L and 13R, EVFs 21L and 21R, and eyepieces 22L and 22R in this order from a subject (not shown) side to the side of a left eye EL and a right eye ER of the user. The objective lenses 11L and 11R, the imaging elements 12L and 12R, and the LSIs 13L and 13R are housed in a casing 14. The EVF 21L and the eyepiece 22L are housed in an eyepiece barrel 23L. The EVF 21R and the eyepiece 22R are housed in an eyepiece barrel 23R.

The imaging elements 12L and 12R convert image light entering from the objective lenses 11L and 11R into an electric signal. The imaging elements 12L and 12R are formed by a CMOS (Complementary Metal Oxide Semiconductor) imager or the like.

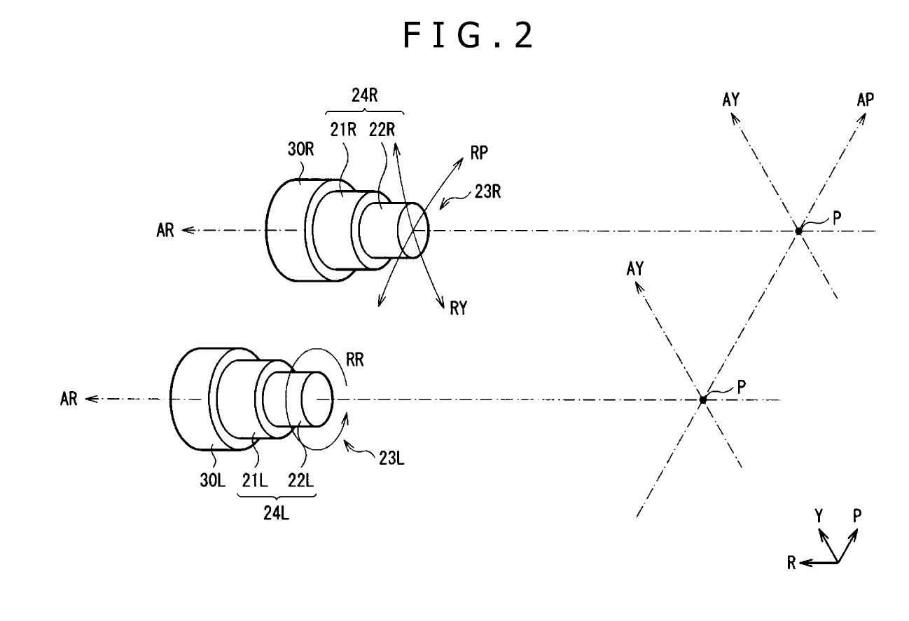

FIG. 2 schematically shows an internal configuration of the eyepiece barrels 23L and 23R. The EVF 21L, the eyepiece 22L, and a base 30L, for example, are arranged within the eyepiece barrel 23L. The EVF 21R, the eyepiece 22R, and a base 30R, for example, are arranged within the eyepiece barrel 23R.

The EVF 21L generates an image on the basis of the electric signal converted by the imaging element 12L. The EVF 21L is formed by a display element such as a liquid crystal display panel or the like. The user can observe the image displayed in the EVF 21L in a state of being magnified by the eyepiece 22L. For diopter adjustment, the eyepiece 22L is moved along a guide shaft (not shown), whereby a distance between the eyepiece 22L and the EVF 21L can be adjusted. The EVF 21L and the eyepiece 22L are housed in an exterior member (not shown) to form an EVF lens unit 24L. The base 30L will be described later.

The EVF 21R generates an image on the basis of the electric signal converted by the imaging element 12R. The EVF 21R is formed by a display element such as a liquid crystal display panel or the like. The user can observe the image displayed in the EVF 21R in a state of being magnified by the eyepiece 22R. For diopter adjustment, the eyepiece 22R is moved along a guide shaft (not shown), whereby a distance between the eyepiece 22R and the EVF 21R can be adjusted. The EVF 21R and the eyepiece 22R are housed in an exterior member (not shown) to form an EVF lens unit 24R. The base 30R will be described later.

The angle of rotation (angle of roll) of the EVF 21L about an axis AR in a longitudinal direction which axis passes through a specific position P (which axis will hereinafter be also referred to simply as a “longitudinal axis AR”) (direction of an arrow RR) can be adjusted with respect to the EVF 21R. The electronic binoculars thereby allow the angles of roll of the EVF 21L and the EVF 21R to be adjusted.

In addition, preferably, the angle of rotation (angle of pitch) of the EVF 21R about an axis AP that passes through a specific position P and which axis is parallel with a direction of width (which axis will hereinafter be also referred to simply as a “lateral axis AP”) (direction of an arrow RP), and the angle of rotation (angle of yaw) of the EVF 21R about an axis AY that passes through the specific position P and which axis is parallel with a direction of height (which axis will hereinafter be also referred to simply as a “vertical axis AY”) (direction of an arrow RY) can be adjusted with respect to the EVF 21L. Reasons for this are as follows. A method can be adopted in which one of the EVF 21L and the EVF 21R has all of structures for adjusting the three angles, that is, the angle of roll, the angle of pitch, and the angle of yaw, and the angle of roll, the angle of pitch, and the angle of yaw are adjusted with respect to the other EVF without an adjusting structure. However, when one of the angle of roll, the angle of pitch, and the angle of yaw is adjusted in one of the EVF 21L and the EVF 21R, and the other two angles are adjusted in the other of the EVFs 21L and 21R, an increase in device size can be avoided, and an internal region can be used effectively.

The “specific positions” in this case are preferably eye points, that is, positions determined by a designer as “reference positions for viewing with eyes.” More specifically, in positional relation with the EVFs 21L and 21R, the eyepieces 22L and 22R, and the left eye EL and the right eye ER of the user, the specific positions are positions in the rear of the eyepieces 22L and 22R (on the side of the left eye EL and the right eye ER of the user) at which positions no shading occurs. Shading is a phenomenon in which a constituent member chips a corner of an image as viewed from a lens, or reduces an amount of peripheral light and thus darkens an image.

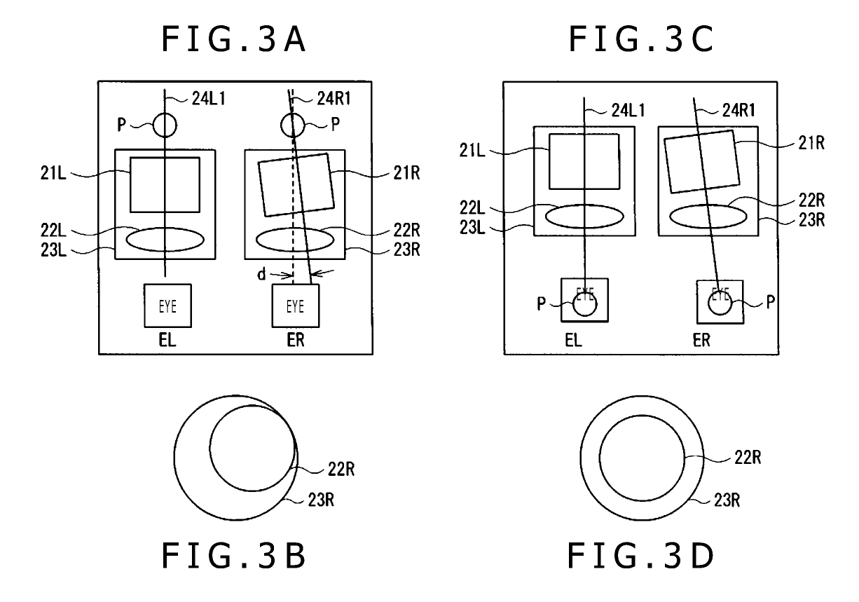

Incidentally, the specific positions P can be theoretically adjusted to any position as long as the EVFs 21L and 21R or the like can be rotated. For example, FIG. 3A shows an example of adjusting the angle of pitch of the EVF 21R with the specific positions P set at positions in front of the EVFs 21L and 21R (on the subject side). In this case, however, the left and right positions of the units as a whole of the eyepieces 22L and 22R and the EVFs 21L and 21R are shifted after adjustment, and may be adjusted in a state unsuitable for actual use as binoculars. While correct eye positions EL and ER (eyepiece barrels 23L and 23R) in the state of a product should be on axes 24L1 and 24R1 passing through the specific positions P, a displacement d occurs between the eye position ER and the axis 24R1 in FIG. 3A. Thus, as shown in FIG. 3B, looking through the eyepiece barrel 23R shows that the eyepiece 22R is displaced, and great shading may occur. In addition, distances between the eyes EL and ER and the eyepieces 22L and 22R on the left and the right are changed, so that lens performance on the left and the right may not be maintained.

On the other hand, FIG. 3C shows an example of adjusting the angle of pitch of the EVF 21R with the specific positions P set at eye points. In this case, correct eye positions EL and ER (eyepiece barrels 23L and 23R) in the state of a product are on axes 24L1 and 24R1 passing through the specific positions P. Hence, as shown in FIG. 3D, looking through the eyepiece barrel 23R shows that the eyepiece 22R is situated at a center, and shading is reduced. For the above reasons, the specific positions P are preferably eye points.

### (Roll Angle Adjusting Mechanism)

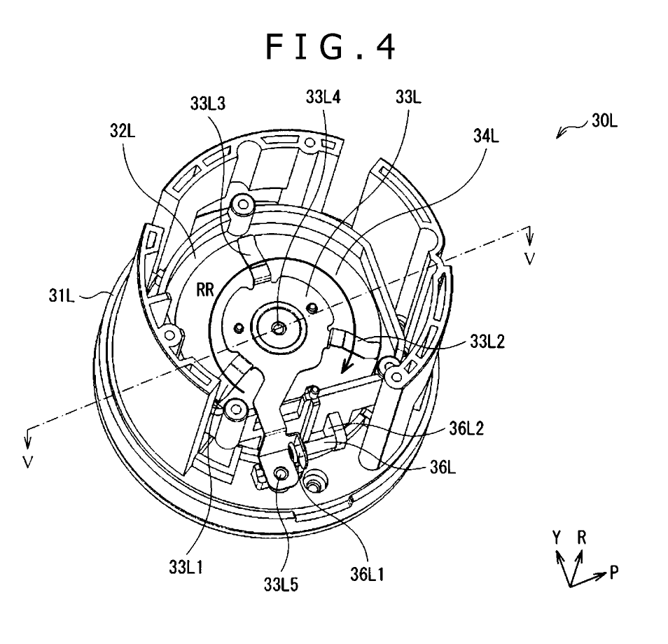

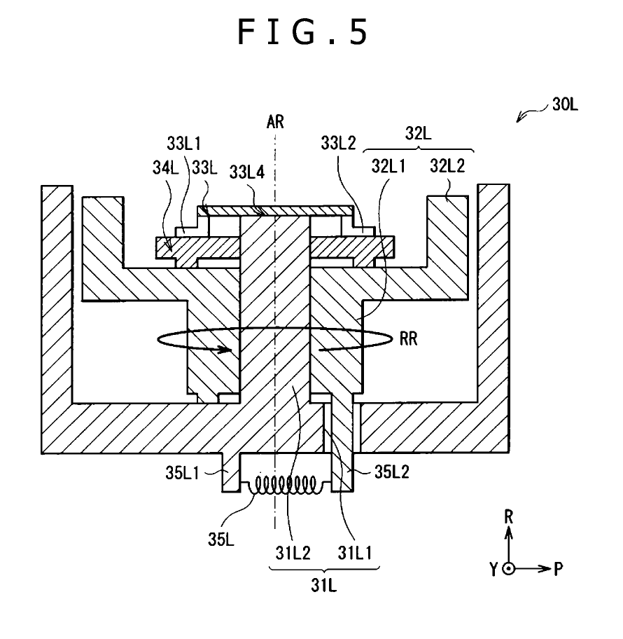

Description in the following will be made of a mechanism for adjusting the angle of roll of the EVF 21L. FIG. 4 shows a general constitution of the base 30L shown in FIG. 2. FIG. 5 schematically shows a sectional constitution of the base 30L cut by a plane including the diameter of the base 30L.

The base 30L is a part for attaching the EVF lens unit 24L and coupling the eyepiece barrel 23L with the casing 14. The base 30L includes for example a first fixed member 31L, a first rotating member 32L, a first holding leaf spring 33L, a first holding member 34L, a first adjusting spring 35L (not shown in FIG. 4 but shown in FIG. 5), and a first adjusting screw 36L. However, the first adjusting spring 35L is schematically shown in FIG. 5.

The first fixed member 31L includes for example a fixed main body section 31L1 and a rotation supporting shaft 31L2. The fixed main body section 31L1 is for example a cylindrical part opening at one end thereof. The rotation supporting shaft 31L2 is disposed in the center of the bottom surface of the fixed main body section 31L1. The rotation supporting shaft 31L2 supports the first rotating member 32L and serves as a central axis of rotation for the first rotating member 32L. That is, the rotation supporting shaft 31L2 coincides with the longitudinal axis AR, and coincides with the optical axis of the eyepiece 22L.

As indicated by an arrow RR, the first rotating member 32L is rotated about the rotation supporting shaft 31L2 of the first fixed member 31L, and thereby rotates the EVF lens unit 24L about the longitudinal axis AR (roll rotation). The first rotating member 32L includes for example a rotating main body section 32L1 and an attaching section 32L2. The rotating main body section 32L1 is fitted onto the rotation supporting shaft 31L2 of the first fixed member 31L, and is rotatable about the longitudinal axis AR. The attaching section 32L2 is a part for attaching the EVF lens unit 24L. The attaching section 32L2 is disposed in the shape of a flange on the periphery of the rotating main body section 32L1.

The first holding leaf spring 33L has the first rotating member 32L sandwiched between the first holding leaf spring 33L and the first fixed member 31L, and thereby removes wobbles and enables precise roll angle adjustment. The first holding leaf spring 33L holds the first holding member 34L and the first rotating member 32L with three legs 33L1, 33L2, and 33L3, for example. Meanwhile, the first holding leaf spring 33L is fixed to the first fixed member 31L at two fixing points 33L4 and 33L5. The fixing point 33L4 is for example disposed at an end of the rotation supporting shaft 31L2. The fixing point 33L5 is for example disposed on a peripheral part of the bottom surface of the first fixed member 31L.

The first holding member 34L is to reduce friction between the first holding leaf spring 33L and the first rotating member 32L, and thereby smooth the rotation of the first rotating member 32L. The first holding member 34L is fitted on the rotation supporting shaft 31L2 of the first fixed member 31L together with the first rotating member 32L.

The first adjusting spring 35L and the first adjusting screw 36L are to adjust the angle of roll rotation of the EVF 21L by the first rotating member 32L. Specifically, the first adjusting spring 35L regulates the direction of rotation of the first rotating member 32L in one direction by biasing the first rotating member 32L in a specific direction of rotation (for example a clockwise direction indicated by the arrow RR). Meanwhile, the first adjusting screw 36L linearly moves, by rotation, in a direction of pushing back against the biasing force of the first adjusting spring 35L, and thus adjusts the angle of roll of the first rotating member 32L and the EVF 21L.

The first adjusting spring 35L is for example disposed between a fixed side latching part 35L1 and a rotating side latching part 35L2. The fixed side latching part 35L1 is for example a projection disposed on the bottom surface of the first fixed member 31L. The rotating side latching part 35L2 is for example a projection disposed on the bottom surface of the first rotating member 32L.

The shaft of the first adjusting screw 36L is for example passed through a through hole 36L1 disposed in the side surface of the first fixed member 31L or the first holding leaf spring 33L. The screw point of the first adjusting screw 36L abuts against a projecting surface 36L2 on the side surface of the first rotating member 32L, and pushes the projecting surface 36L2.

### (Pitch Angle Adjusting Mechanism)

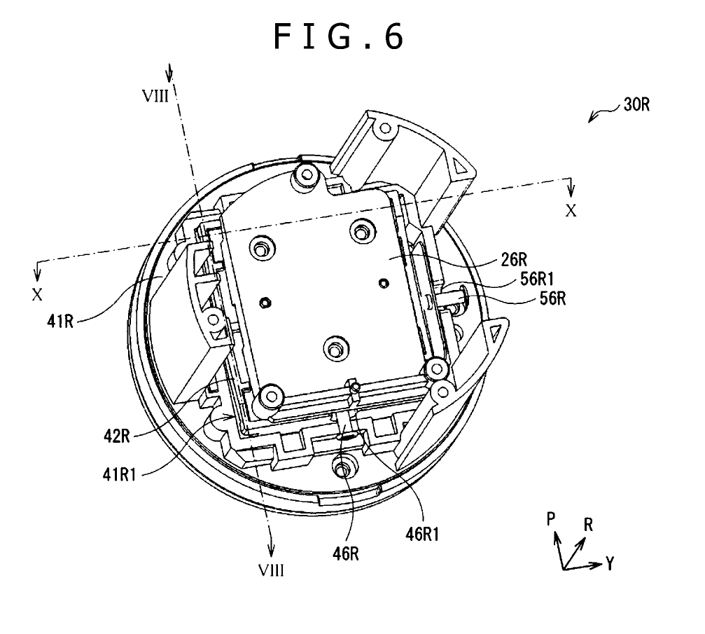

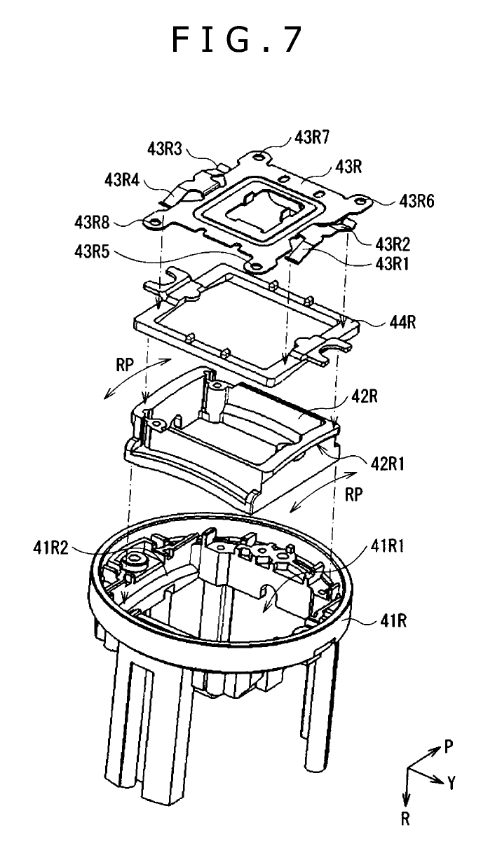

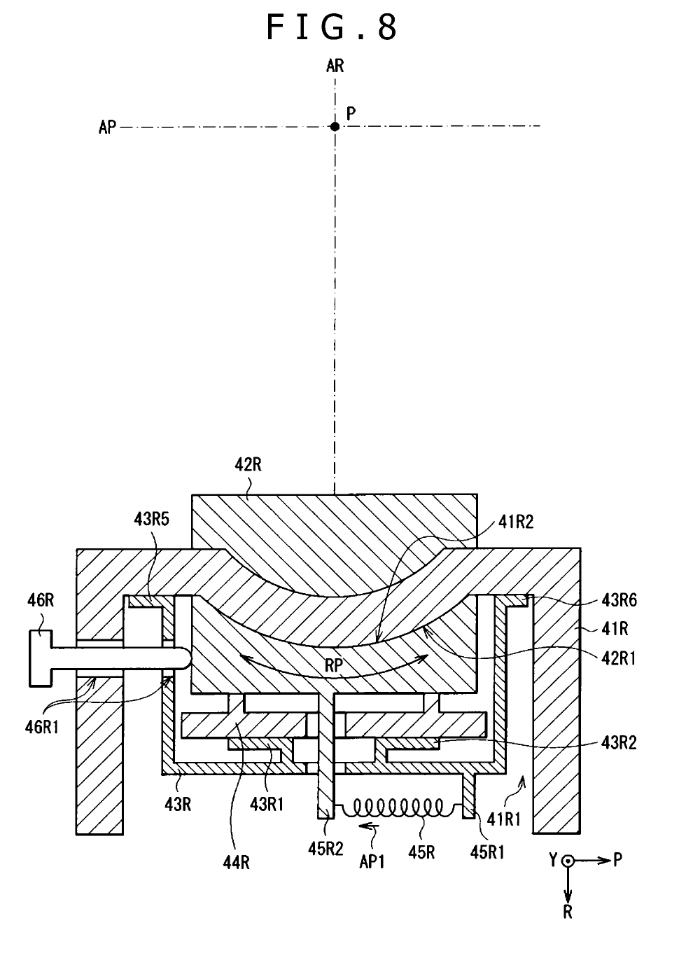

Description will next be made of a mechanism for adjusting the angle of pitch of the EVF 21R. FIG. 6 shows a general constitution of the base 30R shown in FIG. 2. FIG. 7 shows the base 30R in an exploded state. FIG. 8 schematically shows a sectional constitution taken along a line VIII-VIII in FIG. 6.

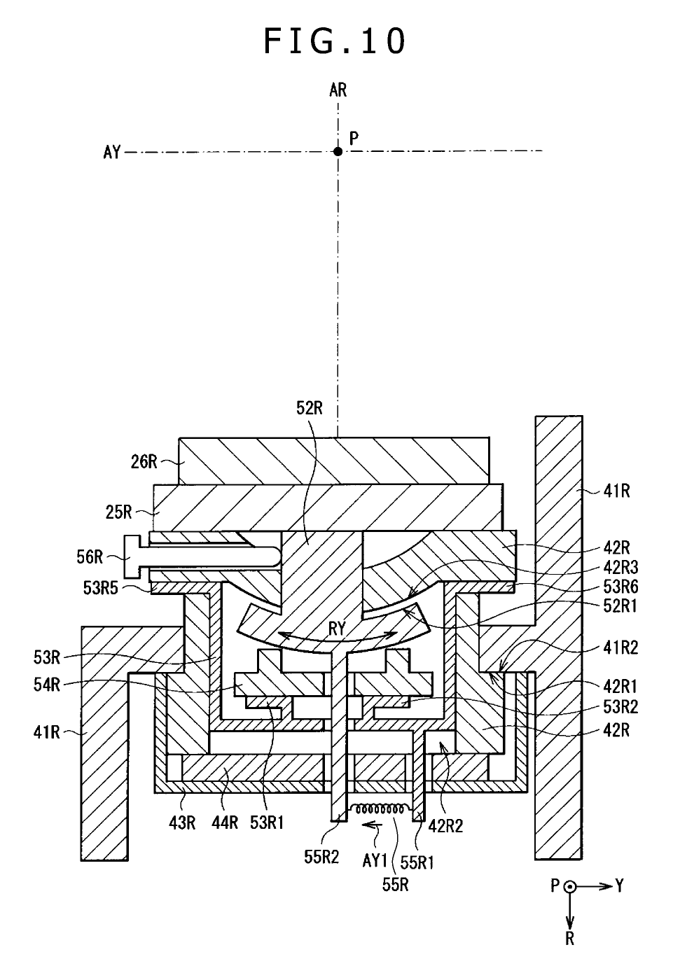

The base 30R is a part for attaching the EVF lens unit 24R and coupling the eyepiece barrel 23R with the casing 14. The base 30R includes for example a second fixed member 41R, a second rotating member 42R, a second holding leaf spring 43R, a second holding member 44R, a second adjusting spring 45R (see FIG. 8), and a second adjusting screw 46R. Incidentally, an attaching member 26R for attaching the EVF lens unit 24R is disposed on the second rotating member 42R with a third rotating member 52R (see FIG. 10) and a retaining member 25R (see FIG. 10) to be described later interposed between the attaching member 26R and the second rotating member 42R. In addition, the second adjusting spring 45R is schematically shown in FIG. 8.

The second fixed member 41R is for example a cylindrical part opening at one end thereof, and has a rectangular opening 41R1 at the center of the bottom surface thereof. A rotation guide 41R2 is disposed on two sides of the opening 41R1 which sides are opposed to each other. The rotation guides 41R2 are curved surfaces supporting the second rotating member 42R and serving as a guide for pitch rotation of the second rotating member 42R about the lateral axis AP in the direction of arrows RP. The rotation guides 41R2 have the sectional shape of an arc having the specific position P as the center thereof.

As indicated by the arrows RP, the second rotating member 42R is rotated about the lateral axis AP described above, and thereby rotates the EVF lens unit 24R about the lateral axis AP (pitch rotation). Specifically, the second rotating member 42R is a rectangular part fitted in the opening 41R1 of the second fixed member 41R. Curved surfaces 42R1 corresponding to the rotation guides 41R2 of the second fixed member 41R are disposed on two sides of the second rotating member 42R which sides are opposed to each other.

The second holding leaf spring 43R has the second rotating member 42R sandwiched between the second holding leaf spring 43R and the lower surface of the second fixed member 41R, and thereby removes wobbles and enables precise pitch angle adjustment. The second holding leaf spring 43R holds the second holding member 44R and the second rotating member 42R with a plurality of (for example four) legs 43R1, 43R2, 43R3, and 43R4, for example. Meanwhile, the second holding leaf spring 43R is fixed to the bottom surface of the second fixed member 41R at a plurality of (for example four) fixing points 43R5, 43R6, 43R7, and 43R8 on the periphery of the opening 41R1.

The second holding member 44R is to reduce friction between the second holding leaf spring 43R and the second rotating member 42R, and thereby smooth the rotation of the second rotating member 42R. The second holding member 44R is fitted in the opening 41R1 of the second fixed member 41R together with the second rotating member 42R.

The second adjusting spring 45R and the second adjusting screw 46R are to adjust the angle of pitch rotation of the EVF 21R by the second rotating member 42R. Specifically, the second adjusting spring 45R regulates the direction of rotation of the second rotating member 42R in one direction by biasing the second rotating member 42R in a specific direction (for example to a left as indicated by an arrow AP1 in FIG. 8). Meanwhile, the second adjusting screw 46R linearly moves, by rotation, in a direction of pushing back against the biasing force of the second adjusting spring 45R, and thus adjusts the angle of pitch of the second rotating member 42R and the EVF 21R.

Such a second adjusting spring 45R is for example disposed between a fixed side latching part 45R1 and a rotating side latching part 45R2. The fixed side latching part 45R1 is for example a projection disposed on the bottom surface of the second fixed member 41R (or the second holding leaf spring 43R fixed to the second fixed member 41R). The rotating side latching part 45R2 is for example a projection disposed on the bottom surface of the second rotating member 42R.

The shaft of the second adjusting screw 46R is for example passed through a through hole 46R1 disposed in the side surface of the second fixed member 41R or the second holding leaf spring 43R. The screw point of the second adjusting screw 46R abuts against the side surface of the second rotating member 42R, and pushes the second rotating member 42R.

### (Yaw Angle Adjusting Mechanism)

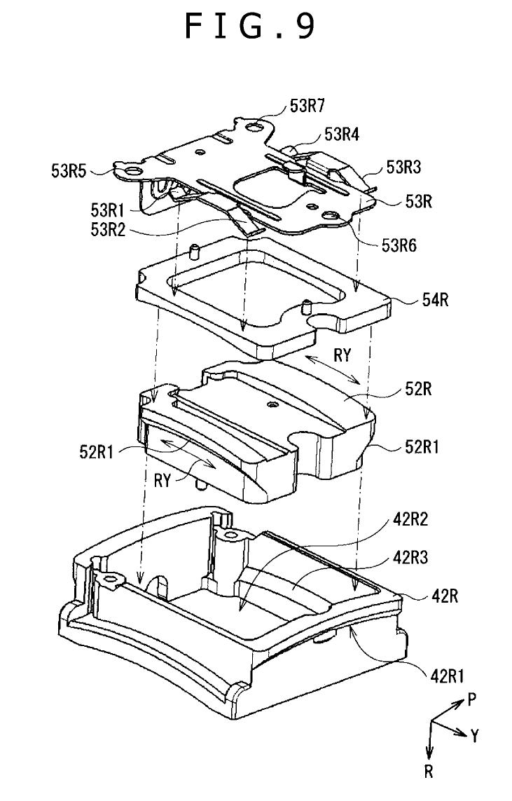

Description will next be made of a mechanism for adjusting the angle of yaw of the EVF 21R. FIG. 9 shows the second rotating member 42R shown in FIG. 7 and FIG. 8 in an exploded state. FIG. 10 schematically shows a sectional constitution taken along a line X-X in FIG. 6.

A third rotating member 52R, a third holding leaf spring 53R, a third holding member 54R, a third adjusting spring 55R (see FIG. 10), and a third adjusting screw 56R (see FIG. 6) are disposed on the inside and the periphery of the second rotating member 42R. Incidentally, the third adjusting spring 55R is schematically shown in FIG. 10.

The second rotating member 42R for example has a rectangular opening 42R2 at the center of the bottom surface thereof. A rotation guide 42R3 is disposed on two sides of the opening 42R2 which sides are opposed to each other. The rotation guides 42R3 are curved surfaces supporting the third rotating member 52R and serving as a guide for rotation of the third rotating member 52R about the vertical axis AY. The rotation guides 42R3 have the sectional shape of an arc having the specific position P as a center thereof.

As indicated by arrows RY, the third rotating member 52R is rotated about the vertical axis AY described above, and thereby rotates the EVF lens unit 24R about the vertical axis AY (yaw rotation). Specifically, the third rotating member 52R is a rectangular part fitted in the opening 42R2 of the second rotating member 42R. Curved surfaces 52R1 corresponding to the rotation guides 42R3 of the second rotating member 42R are disposed on two sides of the third rotating member 52R which sides are opposed to each other. The third rotating member 52R is fixed to the attaching member 26R with the retaining member 25R between the third rotating member 52R and the attaching member 26R.

The third holding leaf spring 53R has the third rotating member 52R sandwiched between the third holding leaf spring 53R and the lower surface of the second rotating member 42R, and thereby removes wobbles and enables precise yaw angle adjustment. The third holding leaf spring 53R holds the third holding member 54R and the third rotating member 52R with a plurality of (for example four) legs 53R1, 53R2, 53R3, and 53R4, for example. Meanwhile, the third holding leaf spring 53R is fixed to the bottom surface of the second rotating member 42R at a plurality of (for example three) fixing points 53R5, 53R6, and 53R7 on the periphery of the opening 42R2.

The third holding member 54R is to reduce friction between the third holding leaf spring 53R and the third rotating member 52R, and thereby smooth the rotation of the third rotating member 52R. The third holding member 54R is fitted in the opening 42R2 of the second rotating member 42R together with the third rotating member 52R.

The third adjusting spring 55R and the third adjusting screw 56R are to adjust the angle of yaw rotation of the EVF 21R by the third rotating member 52R. Specifically, the third adjusting spring 55R regulates the direction of rotation of the third rotating member 52R in one direction by biasing the third rotating member 52R in a specific direction (for example to a left as indicated by an arrow AY1 in FIG. 10). Meanwhile, the third adjusting screw 56R linearly moves, by rotation, in a direction of pushing back against the biasing force of the third adjusting spring 55R, and thus adjusts the angle of yaw of the third rotating member 52R and the EVF 21R.

Such a third adjusting spring 55R is for example disposed between a fixed side latching part 55R1 and a rotating side latching part 55R2. The fixed side latching part 55R1 is for example a projection disposed on the bottom surface of the second rotating member 42R (or the third holding leaf spring 53R fixed to the second rotating member 42R). The rotating side latching part 55R2 is for example a projection disposed on the bottom surface of the third rotating member 52R.

The shaft of the third adjusting screw 56R is for example passed through a through hole 56R1 (see FIG. 6) disposed in the side surface of the second rotating member 42R or the third holding leaf spring 53R. The screw point of the third adjusting screw 56R abuts against the side surface of the third rotating member 52R, and pushes the third rotating member 52R.

The angles of rotation of the EVFs 21L and 21R in the electronic binoculars can be adjusted as follows, for example.

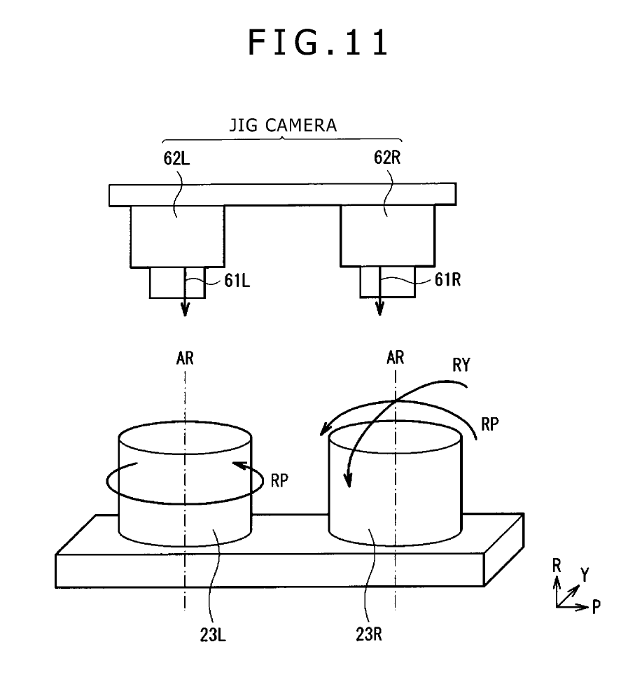

As shown in FIG. 11, a chart image is displayed in the EVFs 21L and 21R in the eyepiece barrels 23L and 23R whose assembly has been completed. The chart images are taken by two jig cameras 62L and 62R whose optical axes 61L and 61R are adjusted to be parallel with each other, and adjustment is made while the chart images are compared with each other. At this time, focus is set to a point at infinity. In addition, the diopter of the eyepieces 22L and 22R is adjusted to 0 Diop (diopter).

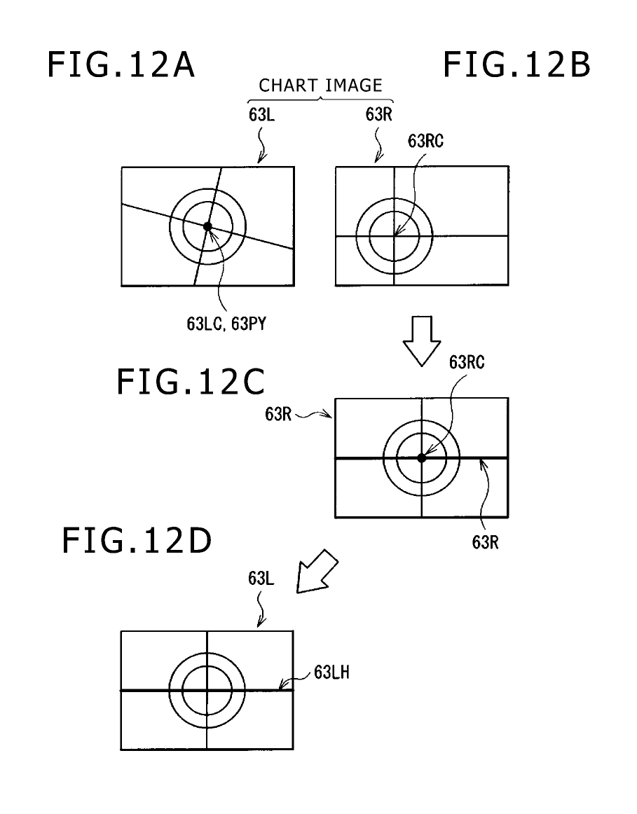

FIG. 12A and FIG. 12B show initial positions of the chart images 63L and 63R taken by the jig cameras 62L and 62R. The angle of roll of the EVF 21R on the right is determined at a time of completion of assembly, whereas the angle of yaw and the angle of pitch of the EVF 21R are in an adjustable state. Thus, at the initial position of the chart image 63R, the angle of pitch and the angle of yaw are observed as vertical and horizontal displacements of the central point 63RC of the chart image 63R, but the angle of roll can be made infinitely closer to a desired inclination (for example the horizontal) by increasing the accuracy of the assembly.

On the other hand, the angle of pitch and the angle of yaw of the EVF 21L on the left are determined at the time of completion of assembly, whereas the angle of roll of the EVF 21L is in an adjustable state. Thus, at the initial position of the chart image 63L, the angle of roll is in a rotated state from a desired angle (for example the horizontal), but the angle of pitch and the angle of yaw can be made infinitely closer to a desired angle by increasing the accuracy of the assembly. That is, the central point 63LC of the chart image 63L can be set at a desired position (for example the center of a screen). This position is set as a pitch and yaw reference point 63PY.

Next, as shown in FIG. 12C, the angle of pitch of the eyepiece barrel 23R on the right is adjusted by using the second adjusting screw 46R. In addition, the angle of yaw of the eyepiece barrel 23R is adjusted by using the third adjusting screw 56R. Thereby the central point 63RC of the chart image 63R observed in the EVF 21R on the right is adjusted to the pitch and yaw reference point 63PY of the EVF 21L on the left. In this state, a chart horizontal line is set as a roll reference line 63R.

Next, as shown in FIG. 12D, the angle of roll of the eyepiece barrel 23L on the left is adjusted by using the first adjusting screw 36L so that a horizontal line 63LH of the chart image 63L observed in the EVF 21L on the left is set parallel with the roll reference line 63R of the EVF 21R on the right. Thus, the adjustment of the angles of rotation of the EVFs 21L and 21R is completed.

In the electronic binoculars, the imaging elements 12L and 12R convert image light entering from the objective lenses 11L and 11R into an electric signal. The EVFs 21L and 21R generates an image on the basis of the electric signals converted by the imaging elements 12L and 12R. The images are magnified by the eyepieces 22L and 22R, and observed by the user.

In this case, the angle of rotation (angle of roll) of the EVF 21L about the axis AR in the longitudinal direction (longitudinal axis AR) is adjusted with respect to the EVF 21R. Therefore, the parallelisms of the respective images observed with both eyes coincide with each other. Thus, the images are superimposed on each other properly.

Further, the angle of rotation (angle of pitch) of the EVF 21R about the lateral axis AP and the angle of rotation (angle of yaw) of the EVF 21R about the vertical axis AY are adjusted with respect to the EVF 21L. Therefore, the positions in the horizontal direction and the vertical direction of the respective images observed with both eyes coincide with each other. Thus, the images are superimposed on each other more properly, and can be observed comfortably with both eyes.

Thus, in the present embodiment, the angle of rotation (angle of roll) of the EVF 21L about the axis AR in the longitudinal direction (longitudinal axis AR) is made adjustable with respect to the EVF 21R. Therefore, the angles of roll of the EVFs 21L and 21R can be adjusted.

In addition, the angle of rotation (angle of pitch) of the EVF 21R about the axis AP that passes through the specific position P and which axis is parallel with the direction of width (lateral axis AP), and the angle of rotation (angle of yaw) of the EVF 21R about the axis AY that passes through the specific position P and which axis is parallel with the direction of height (vertical axis AY) are made adjustable with respect to the EVF 21L. Thus, an increase in device size can be avoided, and an internal region can be used effectively.

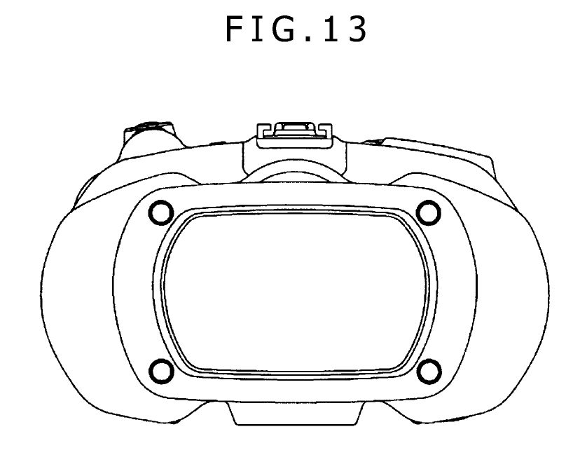

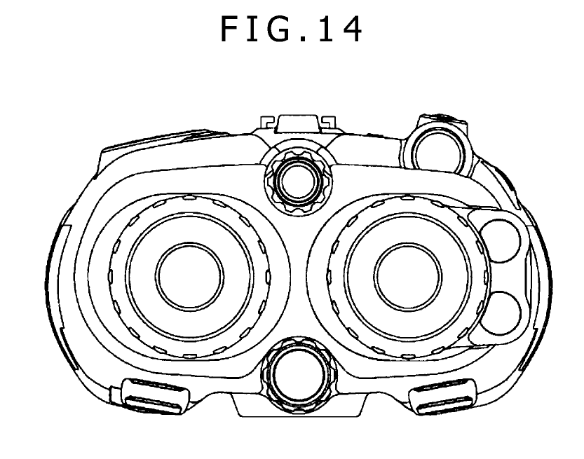

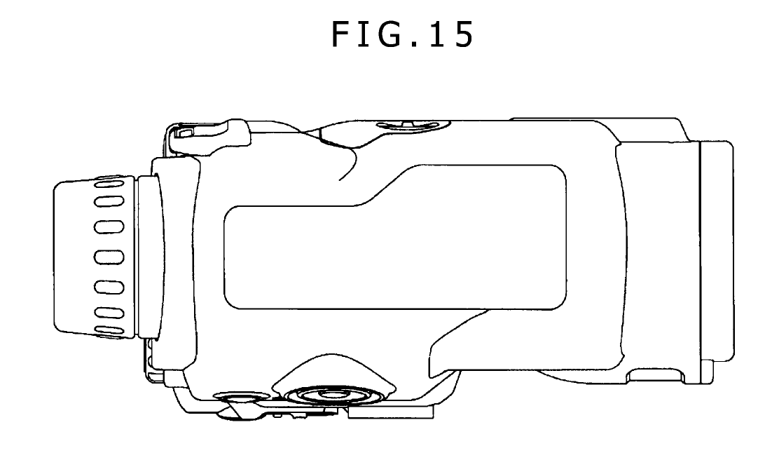

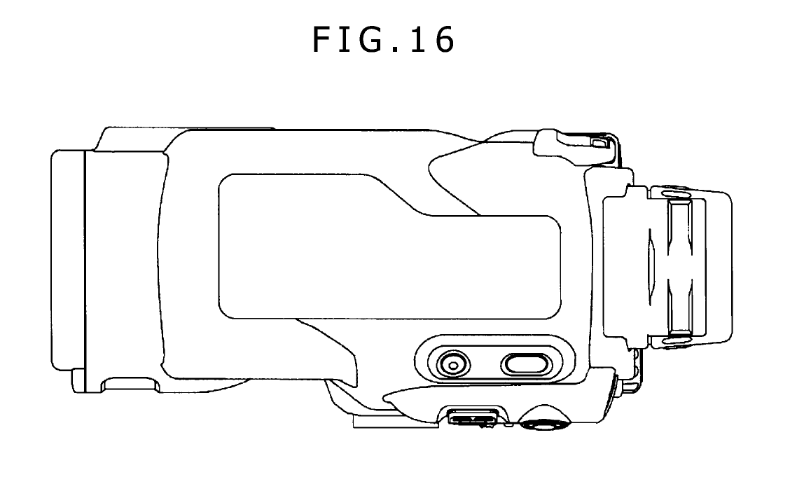

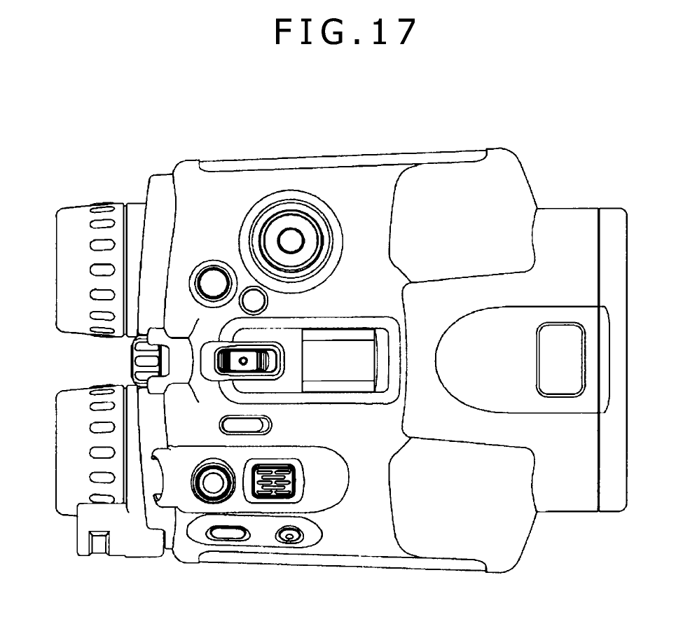

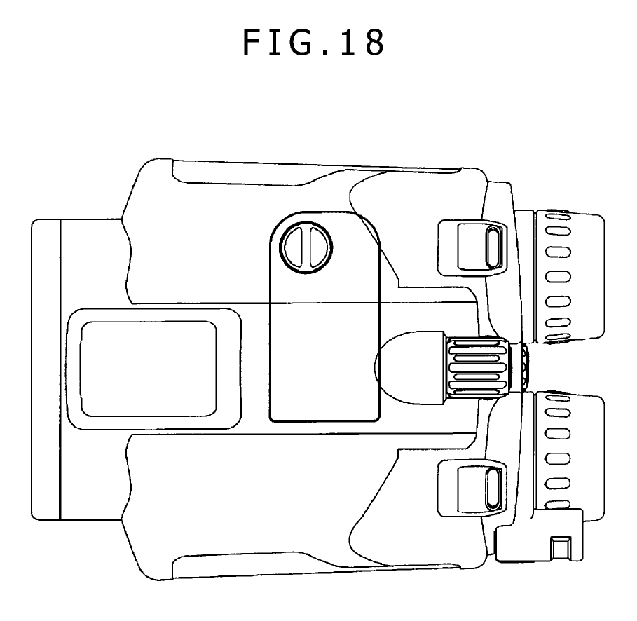

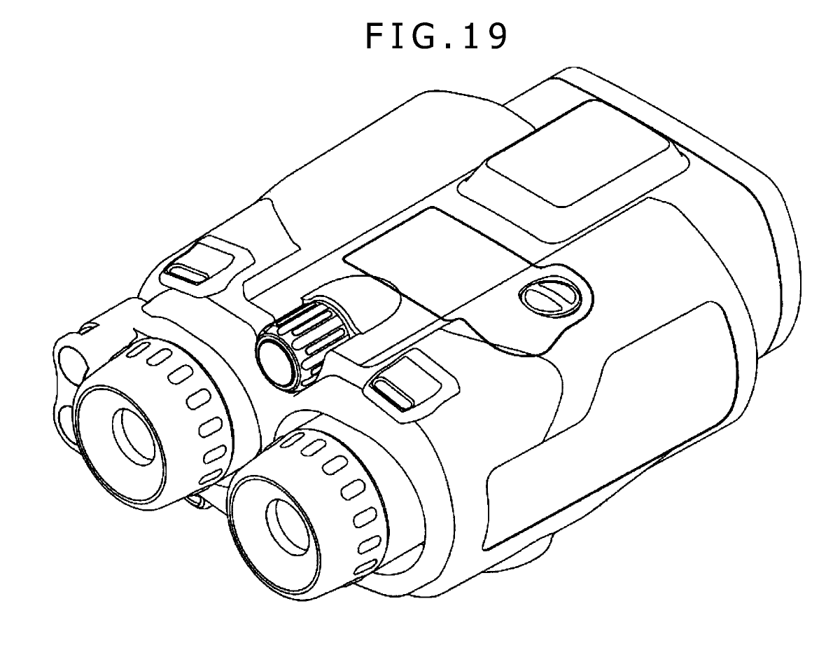

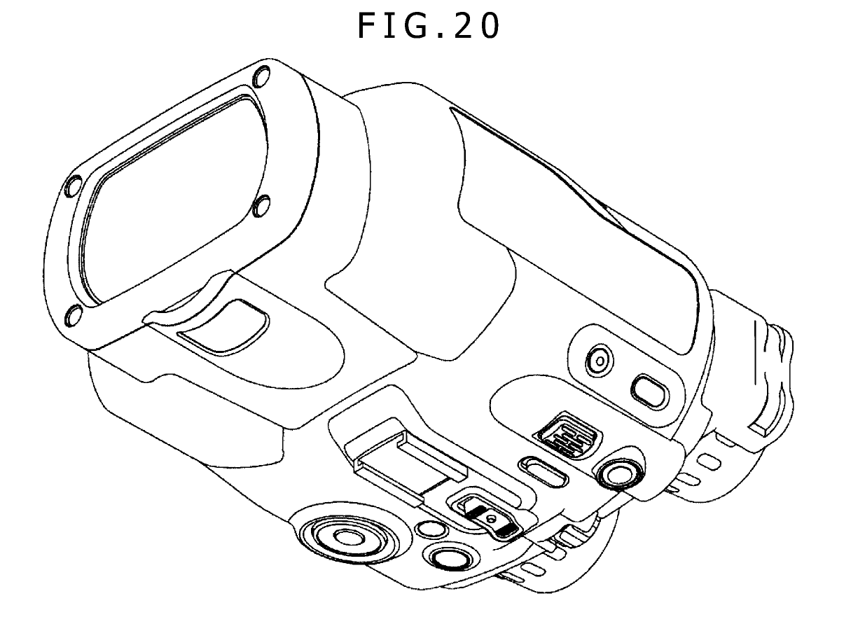

FIGS. 13 to 20 show an example of an external appearance of the electronic binoculars according to the foregoing embodiment. FIG. 13 is a front view. FIG. 14 is a rear view. FIG. 15 is a right side view. FIG. 16 is a left side view. FIG. 17 is a top view. FIG. 18 is a bottom view. FIG. 19 is a perspective view of the external appearance of the electronic binoculars as viewed from the direction of a lower right. FIG. 20 is a perspective view of the external appearance of the electronic binoculars as viewed from the direction of an upper left.

### Second Embodiment

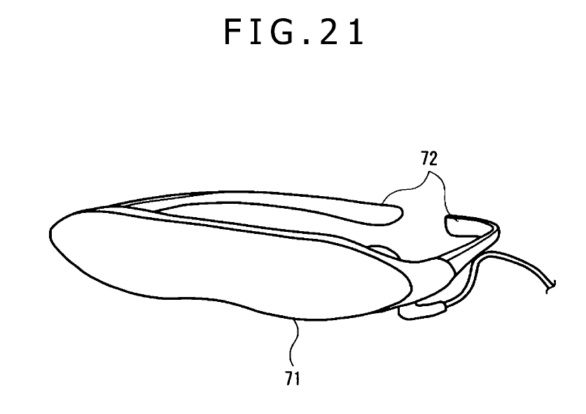

FIG. 21 shows an external appearance of a head-mounted display as a display device according to a second embodiment of the present disclosure. The head-mounted display for example has earpiece parts 72 for mounting on the head part of a user on both sides of a display section 71 having the shape of eyeglasses.

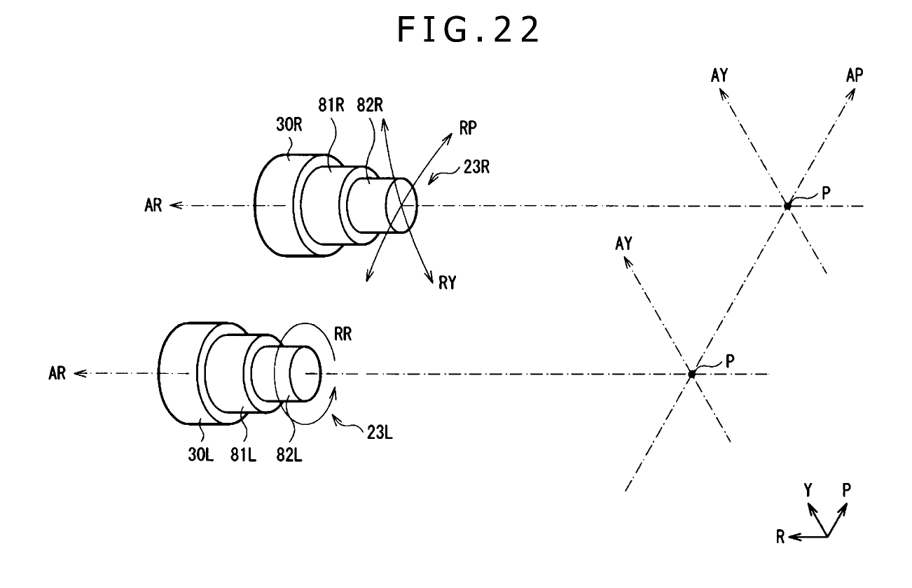

FIG. 22 shows a configuration of the display section 71 shown in FIG. 21. The display section 71 includes for example bases 30L and 30R, display elements 81L and 81R, and eyepieces 82L and 82R similar to those of the first embodiment in order from a side far from the left eye EL and the right eye ER of a user.

The display elements 81L and 81R generate an image on the basis of an electric signal. The display elements 81L and 81R are formed by a liquid crystal display panel, an organic EL (Electroluminescence) display panel, or the like. The user can observe the images displayed on the display elements 81L and 81R in a state of being magnified by the eyepieces 82L and 82R.

The angle of rotation (angle of roll) of the display element 81L about an axis AR in a longitudinal direction (longitudinal axis AR) can be adjusted with respect to the display element 81R. The head-mounted display thereby allows the angles of roll of the display elements 81L and 81R to be adjusted.

In addition, preferably, the angle of rotation (angle of pitch) of the display element 81R about an axis AP that passes through a specific position P and which axis is parallel with a direction of width (lateral axis AP), and the angle of rotation (angle of yaw) of the display element 81R about an axis AY that passes through the specific position P and which axis is parallel with a direction of height (vertical axis AY) are adjustable with respect to the display element 81L. To be sure, a method can be adopted in which one of the display element 81L and the display element 81R has all of structures for adjusting the three angles, that is, the angle of roll, the angle of pitch, and the angle of yaw, and the angle of roll, the angle of pitch, and the angle of yaw are adjusted with respect to the other display element without an adjusting structure. However, when one of the angle of roll, the angle of pitch, and the angle of yaw is adjusted in one of the display elements 81L and 81R, and the other two angles are adjusted in the other of the display elements 81L and 81R, an increase in device size can be avoided, and an internal region can be used effectively.

As in the first embodiment, the “specific positions” in this case are preferably eye points, that is, positions determined by a designer as “reference positions for viewing with eyes.”

The bases 30L and 30R are formed in a similar manner to those of the first embodiment.

### Third Embodiment

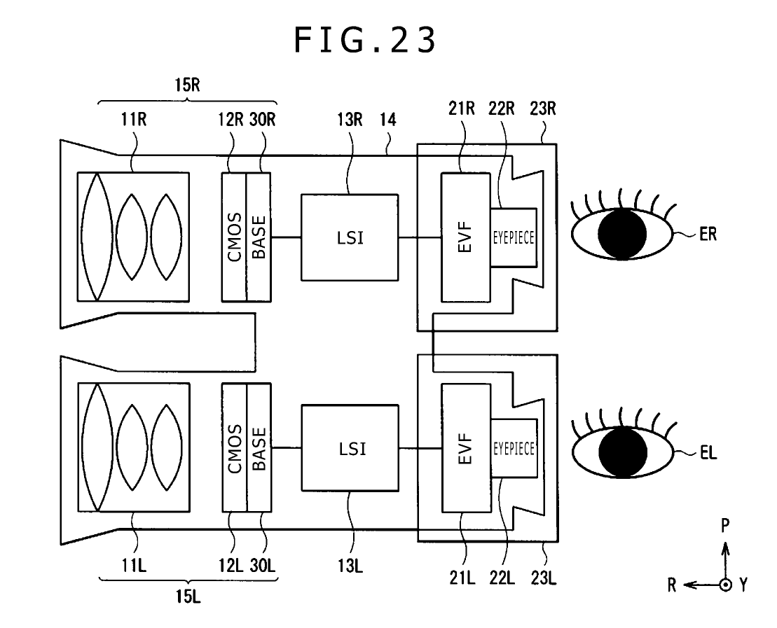

FIG. 23 schematically shows a configuration of electronic binoculars as an imaging device according to a third embodiment of the present disclosure. In the electronic binoculars, bases 30L and 30R similar to those of the first embodiment are provided to imaging elements 12L and 12R, whereby the angle of roll, the angle of pitch, and the angle of yaw of the imaging elements 12L and 12R are made adjustable. Except for this, the configuration, action, and effect of the electronic binoculars are similar to those of the first embodiment.

Specifically, the angle of rotation (angle of roll) of the imaging element 12L about an axis AR in a longitudinal direction (longitudinal axis AR) can be adjusted with respect to the imaging element 12R. The electronic binoculars thereby allow the angles of roll of the imaging elements 12L and 12R to be adjusted.

In addition, preferably, the angle of rotation (angle of pitch) of the imaging element 12R about an axis AP parallel with a direction of width (lateral axis AP), and the angle of rotation (angle of yaw) of the imaging element 12R about an axis AY parallel with a direction of height (vertical axis AY) are adjustable with respect to the imaging element 12L.

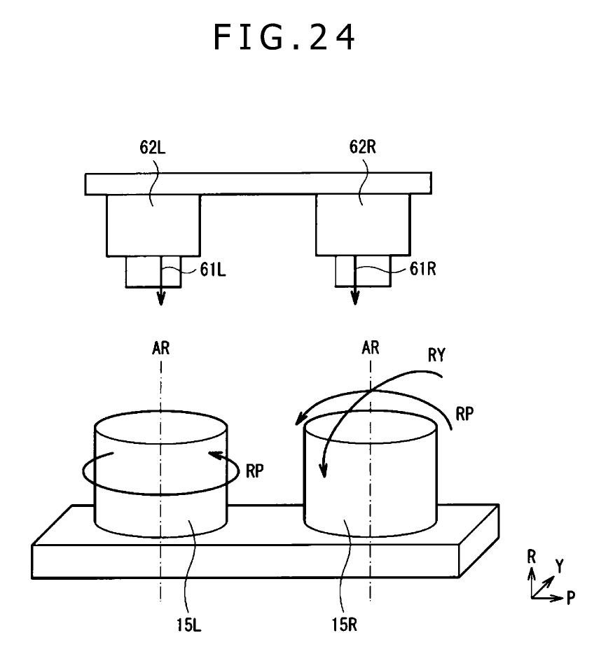

FIG. 24 shows a method for adjusting the angles of rotation of such imaging elements 12L and 12R. An imaging unit 15L is formed by arranging an objective lens 11L and the imaging element 12L on the base 30L. In addition, an imaging unit 15R is formed by arranging an objective lens 11R and the imaging element 12R on the base 30R. As in the first embodiment, it is possible to photograph the imaging units 15L and 15R by jig cameras 62L and 62R, adjust the angle of roll of the imaging element 12L, and adjust the angle of pitch and the angle of yaw of the imaging element 12R.

Incidentally, the first embodiment and the third embodiment can be combined with each other so that bases 30L and 30R similar to those of the first embodiment are provided to both of the EVFs 21L and 21R and the imaging elements 12L and 12R.

The present disclosure has been described above by citing embodiments. However, the present disclosure is not limited to the foregoing embodiments, but is susceptible of various modifications. For example, in the foregoing embodiments, description has been made of a case where the angle of roll is adjusted by the left base 30L, and the angle of pitch and the angle of yaw are adjusted by the right base 30R. However, it is also possible to adjust the angle of roll by the right base 30R, and adjust the angle of pitch and the angle of yaw by the left base 30L.

In addition, combinations of mechanisms for adjusting the three angles of roll, pitch, and yaw are not limited as long as one of the mechanisms is provided to the base 30L (or the base 30R) and the other two mechanisms are provided to the base 30R (or the base 30L). For example, the angle of pitch may be adjusted by the base 30L, and the angle of roll and the angle of yaw may be adjusted by the base 30R. Further, the angle of pitch may be adjusted by the base 30R, and the angle of roll and the angle of yaw may be adjusted by the base 30L. Alternatively, the angle of yaw may be adjusted by the base 30L, and the angle of roll and the angle of pitch may be adjusted by the base 30R. In addition, the angle of yaw may be adjusted by the base 30R, and the angle of roll and the angle of pitch may be adjusted by the base 30L.

Further, for example, the foregoing embodiments have been described by citing a concrete configuration of electronic binoculars or a head-mounted display. However, it is not necessary to include all the constituent elements of the configurations, and other constituent elements may be further provided.

In addition, for example, in the foregoing embodiments, description has been made of electronic binoculars as an example of an imaging device and a head-mounted display as an example of a display device. However, the present technology is widely applicable to twin-lens imaging devices or display devices other than electronic binoculars and head-mounted display.

The present disclosure contains subject matter related to that disclosed in Japanese Priority Patent Application JP 2011-086801 filed in the Japan Patent Office on Apr. 8, 2011, the entire content of which is hereby incorporated by reference.

What is claimed is:

1. An imaging device comprising:
a first element for converting image light into an electric signal or generating an image on the basis of an electric signal; and
a second element for converting image light into an electric signal or generating an image on the basis of an electric signal,
wherein an angle of rotation of said first element about an axis in a longitudinal direction is adjustable with respect to said second element.

2. The imaging device according to claim 1,
wherein an angle of rotation of said second element about an axis passing through a specific position and being parallel with a direction of width, and an angle of rotation of said second element about an axis passing through said specific position and being parallel with a direction of height are adjustable with respect to said first element.

3. The imaging device according to claim 2,
wherein said specific position is an eye point.

4. A display device comprising:
a first element for generating an image on the basis of an electric signal; and
a second element for generating an image on the basis of an electric signal,
wherein an angle of rotation of said first element about an axis in a longitudinal direction is adjustable with respect to said second element.

5. The display device according to claim 4,
wherein an angle of rotation of said second element about an axis passing through a specific position and being parallel with a direction of width, and an angle of rotation of said second element about an axis passing through said specific position and being parallel with a direction of height are adjustable with respect to said first element.

6. The display device according to claim 5,
wherein said specific position is an eye point.
